(19) United States
(12) Patent Application Publication
(10) Pub. No.: US 2025/0149426 A1
(43) Pub. Date: May 8, 2025

(54) PACKAGE STRUCTURE AND MANUFACTURING METHOD THEREOF

(71) Applicant: Unimicron Technology Corp., Taoyuan City (TW)

(72) Inventors: An-Sheng Lee, Hsin-chu County (TW); Chen-Hao Lin, Keelung City (TW); Kai-Ming Yang, Hsinchu County (TW); Pu-Ju Lin, Hsinchu City (TW); Cheng-Ta Ko, Taipei City (TW); Chin-Sheng Wang, Taoyuan City (TW); Tzyy-Jang Tseng, Taoyuan City (TW)

(73) Assignee: Unimicron Technology Corp., Taoyuan City (TW)

(21) Appl. No.: 18/895,309

(22) Filed: Sep. 24, 2024

Related U.S. Application Data
(63) Continuation-in-part of application No. 18/590,958, filed on Feb. 29, 2024.
Application No. 18/590,958 is a continuation-in-part of application No. 18/503,194, filed on Nov. 7, 2023.

(51) Int. Cl. H01L 23/498; H01L 23/00; H01L 25/00; H01L 25/16

(52) U.S. Cl. CPC H01L 23/49833; H01L 23/49811; H01L 23/49838; H01L 23/49866; H01L 25/167; H01L 25/50; H01L 24/08; H01L 24/16; H01L 2224/08225; H01L 2224/16225; H01L 2924/1531

(57) ABSTRACT

A package structure includes a package substrate, an organic interposer and an electronic unit. The package substrate includes a plurality of first pads. The organic interposer is disposed on the package substrate and includes a plurality of second pads. The second pads are directly connected to the first pads to electrically connected the organic interposer to the package substrate. At least one of each of the first pads and each of the second pads includes a pad portion and a plurality of contact portions connecting the pad portion. A first extension direction of the pad portion is different from a second extension direction of the contact portions. The electronic unit is disposed on the organic interposer, wherein the electronic unit is electrically connected to the package substrate through the organic interposer.

### CROSS-REFERENCE TO RELATED APPLICATION

This application is a continuation-in-part application of and claims the priority benefit of U.S. application Ser. No. 18/590,958, filed on Feb. 29, 2024. The prior U.S. application Ser. No. 18/590,958 is a continuation-in-part application of and claims the priority benefit of U.S. application Ser. No. 18/503,194, filed on Nov. 7, 2023. The entirety of each of the above-mentioned patent applications is hereby incorporated by reference herein and made a part of this specification.

### BACKGROUND

### Technical Field

The disclosure relates to a semiconductor structure and a manufacturing method thereof, and in particular to a package structure and a manufacturing method thereof.

### Description of Related Art

The existing application specific integrated circuit (ASIC) packages and integrates a central processing unit (CPU), a graphics processing unit (GPU), a memory and an input/output circuit into a system on a chip (SoC). Therefore, the volume of the SoC is very large. In addition, in terms of process technology, the CPU and the GPU need very fine feature sizes, such as less than 5 nanometers (nm), while the feature size of the input/output circuit is very large, such as 14 nm. This means that the needed process technology is different. Therefore, when the CPU, the GPU, the memory and the input/output circuit are packaged and integrated into the SoC, the yield is low and the cost is high.

### SUMMARY

The disclosure provides a package structure which may have low cost and high structural reliability.

The package structure of the disclosure includes a package substrate, an organic interposer and an electronic unit. The package substrate includes a plurality of first pads. The organic interposer is disposed on the package substrate and includes a plurality of second pads. The second pads are directly connected to the first pads to electrically connected the organic interposer to the package substrate. At least one of each of the first pads and each of the second pads includes a pad portion and a plurality of contact portions connecting the pad portion. A first extension direction of the pad portion is different from a second extension direction of the contact portions. The electronic unit is disposed on the organic interposer, wherein the electronic unit is electrically connected to the package substrate through the organic interposer.

In an embodiment of the disclosure, the first extension direction is perpendicular to the second extension direction.

In an embodiment of the disclosure, the plurality of contact portions comprises a plurality of nanowires.

In an embodiment of the disclosure, a material of the plurality of nanowires comprises copper.

In an embodiment of the disclosure, a thickness of the plurality of nanowires is less than 3 μm.

In an embodiment of the disclosure, the electronic unit comprises a system on a chip, at least one input/output circuit, an optoelectronic assembly, a combination thereof.

The disclosure provides a manufacturing method of a package structure including the following steps. A package substrate and an organic interposer are provided. The package substrate includes a plurality of first pads, and the organic interposer includes a plurality of second pads.

At least one of each of the first pads and each of the second pads comprises a pad portion and a plurality of contact portions connecting the pad portion. A first extension direction of the pad portion is different from a second extension direction of the contact portions. The second pads are connected to the first pads to electrically connected the organic interposer to the package substrate. An electronic unit is provided on the organic interposer, wherein the electronic unit is electrically connected to the package substrate through the organic interposer.

In an embodiment of the disclosure, the manufacturing method of the package structure further includes providing a underfill between the electronic unit and the organic interposer.

In an embodiment of the disclosure, a method of connecting the second pads to the first pads comprises sintering the second pads to the first pads at bonding temperature of 170° C. or welding the plurality of the second pads to the plurality of the first pads at room temperature.

In an embodiment of the disclosure, the contact portions include a plurality of nanowires.

Based on the above, in the design of the package structure of the disclosure, the second pads are directly connected to the first pads to electrically connected the organic interposer to the package substrate, wherein at least one of each of the first pads and each of the second pads includes a pad portion and a plurality of contact portions connecting the pad portion. That is, instead of using the solder ball, the present disclosure directly connects the second pads to the first pads to achieve a stress-free bonding and the pitch between the pads can be effectively reduced (i.e. to less than 100 μm, preferably less than 40 μm), and thus the package structure of the disclosure may have low cost and high structural reliability.

In order to make the aforementioned features and advantages of the disclosure comprehensible, embodiments accompanied with drawings are described in detail as follows.

### BRIEF DESCRIPTION OF THE DRAWINGS

FIG. 1A is a schematic top view of a package structure according to an embodiment of the disclosure.

FIG. 1B is a schematic cross-sectional view along a line I-I of FIG. 1A.

FIG. 1C is a schematic cross-sectional view along a line II-II of FIG. 1A.

FIG. 2 is a schematic top view of a package structure according to another embodiment of the disclosure.

FIG. 3A to FIG. 3H are schematic cross-sectional views illustrating a manufacturing method of package structure according to an embodiment of the disclosure.

FIG. 4A to FIG. 4C are schematic cross-sectional views illustrating partial steps of a manufacturing method of package structure according to another embodiment of the disclosure.

FIG. 5 is a schematic cross-sectional view of a package structure according to an embodiment of the disclosure.

### DESCRIPTION OF THE EMBODIMENTS

Embodiments of the disclosure may be understood together with drawings, and the drawings of the disclosure are also regarded as a part of description of the disclosure. It should be understood that the drawings of the disclosure are not drawn to scale and, in fact, the dimensions of elements may be arbitrarily enlarged or reduced in order to clearly represent the features of the disclosure.

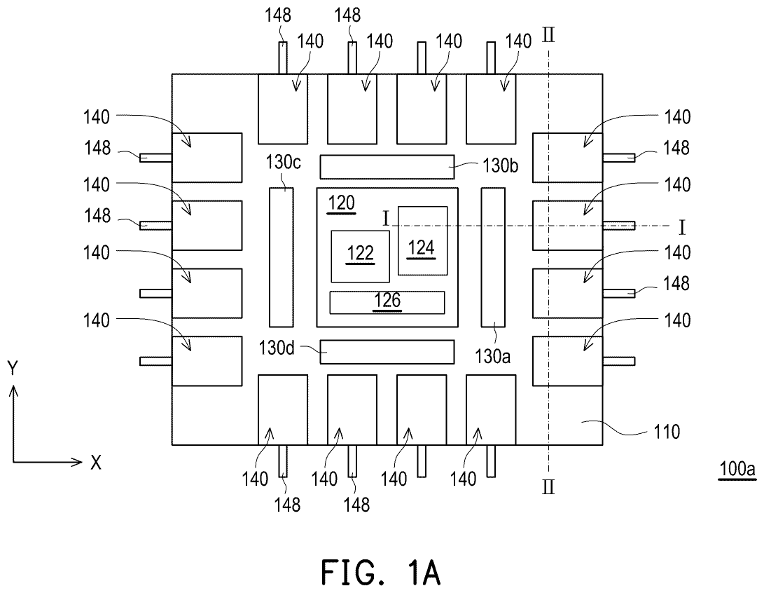

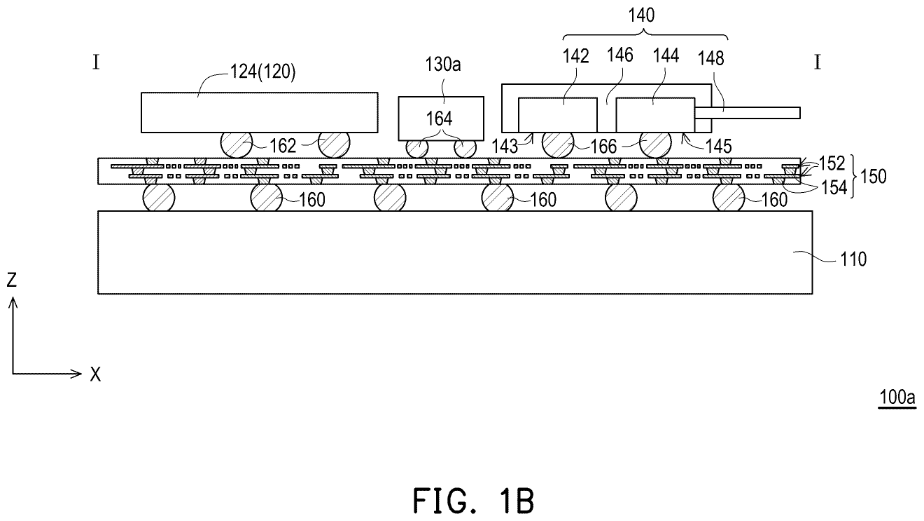

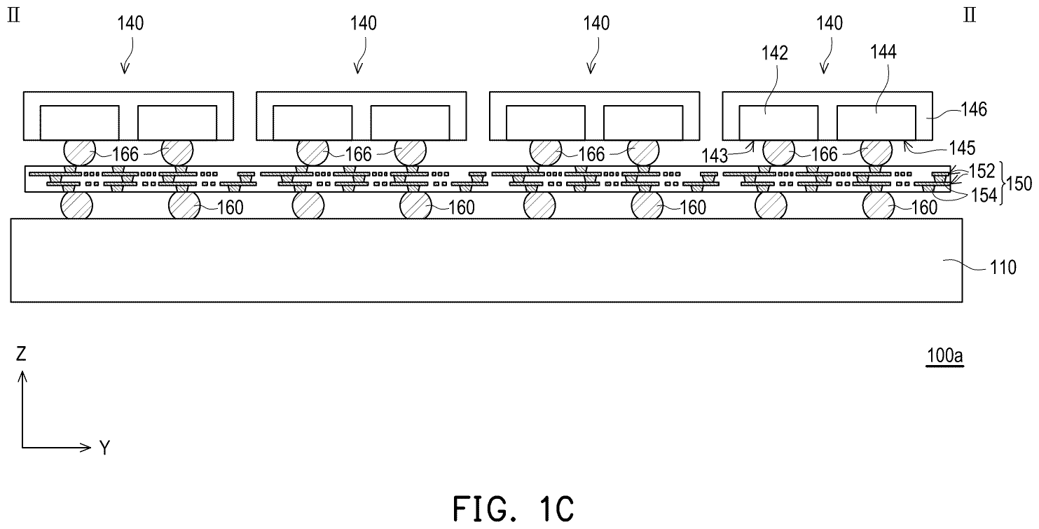

FIG. 1A is a schematic top view of a package structure according to an embodiment of the disclosure. FIG. 1B is a schematic cross-sectional view along a line I-I of FIG. 1A. FIG. 1C is a schematic cross-sectional view along a line II-II of FIG. 1A.

Please refer to FIGS. 1A, 1B and 1C at the same time. In the embodiment, a package structure 100a includes a package substrate 110, a system on a chip (SoC) 120, at least one input/output circuit (four input/output circuits 130a, 130b, 130c and 130d are schematically shown), multiple optoelectronic assemblies 140 and an organic interposer 150. The SoC 120 is disposed on the package substrate 110 and includes a central processing unit (CPU) 122, a graphics processing unit (GPU) 124 and a memory 126. The input/output circuits 130a, 130b, 130c and 130d are disposed on the package substrate 110, and located on organic interposer 150. The optoelectronic assemblies 140 are separately disposed on the package substrate 110, located on the organic interposer 150, and surround the SoC 120 and the input/output circuits 130a, 130b, 130c and 130d. The organic interposer 150 is separately fabricated and disposed on the package substrate 110. The SoC 120, the input/output circuits 130a, 130b, 130c and 130d and the optoelectronic assemblies 140 are electrically connected to the package substrate 110 through the organic interposer 150.

In detail, the input/output circuits 130a, 130b, 130c and 130d of the embodiment are separated from each other, surround the SoC 120 and are located between the SoC 120 and the optoelectronic assemblies 140. That is to say, the input/output circuits 130a, 130b, 130c and 130d and the SoC 120 in the embodiment are independent components. Since the SoC 120 of the embodiment does not include the input/output circuits 130a, 130b, 130c and 130d, compared with the existing technology, in which the CPU, the GPU, the memory and the input/output circuit are packaged and integrated into the SoC, the SoC 120 of the embodiment may have a smaller volume. Furthermore, since the input/output circuits 130a, 130b, 130c and 130d and the SoC 120 are independent components, the input/output circuits 130a, 130b, 130c and 130d and the SoC 120 may be formed using different process technology according to the feature sizes. Therefore, the SoC 120 of the embodiment may have higher yield and lower production cost. In addition, because the input/output circuits 130a, 130b, 130c and 130d are split from each other and surround the SoC 120, the transmission paths for the optoelectronic assemblies 140 to enter the SoC 120 through the input/output circuits 130a, 130b, 130c and 130d are shorter, which may effectively reduce parasitic capacitance.

In short, the embodiment separates a large-sized input/output circuit from a large-sized SoC in the existing technology so that the size of the SoC 120 may be smaller, and may effectively improve semiconductor manufacturing yield and effectively reduce manufacturing cost. In addition, splitting the large-sized input/output circuit into the four input/output circuits 130a, 130b, 130c and 130d may make semiconductor manufacturing yield higher and effectively reduce manufacturing cost.

Please refer to FIGS. 1B and 1C at the same time. Each of the optoelectronic assemblies 140 in the embodiment includes an electronic integrated circuit 142, a photonic integrated circuit 144 and an encapsulant 146. The encapsulant 146 covers the electronic integrated circuit 142 and the photonic integrated circuit 144, and exposes a first bottom surface 143 of the electronic integrated circuit 142 and a second bottom surface 145 of the photonic integrated circuit 144. In addition, each of the optoelectronic assemblies 140 further includes an optical fiber cable 148, and the optical fiber cable 148 is connected to the photonic integrated circuit 144.

Furthermore, the organic interposer 150 in the embodiment includes a redistribution layer structure. The redistribution layer structure includes multiple redistribution lines 152 and multiple conductive blind holes 154, and the redistribution lines 152 may be electrically connected to each other through the conductive blind holes 154. In an embodiment, the line width and line spacing of the redistribution lines 152 are, for example, 2 microns, which means that the redistribution lines 152 are fine line layers.

In addition, the package structure 100a of the embodiment further includes multiple conductive members 160, and the conductive members 160 are disposed between the organic interposer 150 and the package substrate 110. The organic interposer 150 is electrically connected to the package substrate 110 through the conductive members 160. In an embodiment, each of the conductive members 160 may be, for example, a solder ball. In addition, in the embodiment, the package structure 100a further includes multiple first conductive members 162, multiple second conductive members 164 and multiple third conductive members 166. The first conductive members 162 are disposed between the SoC 120 and the organic interposer 150, and the SoC 120 is electrically connected to the organic interposer 150 through the first conductive members 162. The second conductive members 164 are disposed between the input/output circuits 130a, 130b, 130c and 130d and the organic interposer 150, and the input/output circuits 130a, 130b, 130c and 130d are electrically connected to the organic interposer 150 through the second conductive members 164. The third conductive members 166 are disposed between the optoelectronic assemblies 140 and the organic interposer 150, and the optoelectronic assemblies 140 are electrically connected to the organic interposer 150 through the third conductive members 166. It should be noted that the forms of the first conductive member 162, the second conductive member 164, the third conductive member 166 and the organic interposer 150 are only shown as an example, even though the conductive member are not connected to the redistribution line or and the conductive blind hole of the organic interposer in the cross section shown in FIG. 1B and FIG. 1C, they may still be connected in other cross-sections not shown. In an embodiment, each of the first conductive members 162, each of the second conductive members 164 and each of the third conductive members 166 are each, for example, a bump or a copper pillar with a solder bump cap.

In short, since the SoC 120 including the CPU 122, the GPU 124 and the memory 126 and the input/output circuits 130a, 130b, 130c and 130d are independent components respectively, compared with the existing technology, in which the CPU, the GPU, the memory and the input/output circuit are packaged and integrated into the SoC, due to lack of the input/output circuits, the SoC 120 of the embodiment will have a smaller volume, high yield and lower cost, and thus, the package structure 100a of the embodiment may have low cost and high structural reliability.

Other embodiments are described below for illustrative purposes. It must be noted here that the following embodiments use the element numerals and part of the contents of the foregoing embodiments, the same numerals are used to denote the same or similar elements, and the description of the same technical content is omitted. For the description of the omitted parts, reference may be made to the foregoing embodiments, and thus the description is not repeated in the following embodiments.

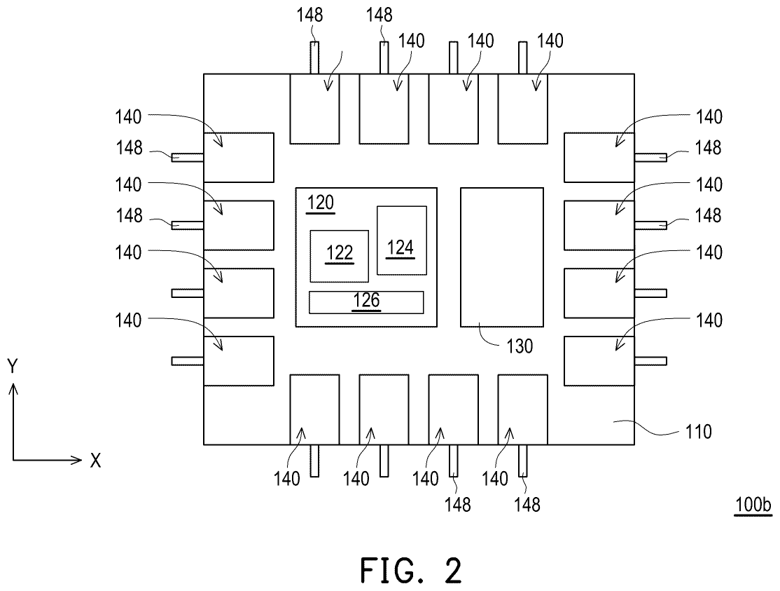

FIG. 2 is a schematic top view of a package structure according to another embodiment of the disclosure. Please refer to FIGS. 1A and 2 at the same time. A package substrate 100b of the embodiment is similar to the above-mentioned package substrate 100a. The main difference between the two is that in the embodiment, the number of input/output circuits 130 is merely one, and the input/output circuit 130 is located next to a side of the SoC 120. Since the embodiment separates a large-sized input/output circuit from a large-sized SoC in the existing technology so that the size of the SoC 120 may be smaller, and will effectively improve semiconductor manufacturing yield and effectively reduce manufacturing cost.

To sum up, in the design of the package structure of the disclosure, the SoC including the CPU, the GPU and the memory and the input/output circuit are independent components. Therefore, compared with the existing technology, in which the CPU, the GPU, the memory and the input/output circuit are packaged and integrated into the SoC, the SoC of the disclosure will have a smaller volume, high yield and low cost, and thus the package structure of the disclosure may have low cost and high structural reliability.

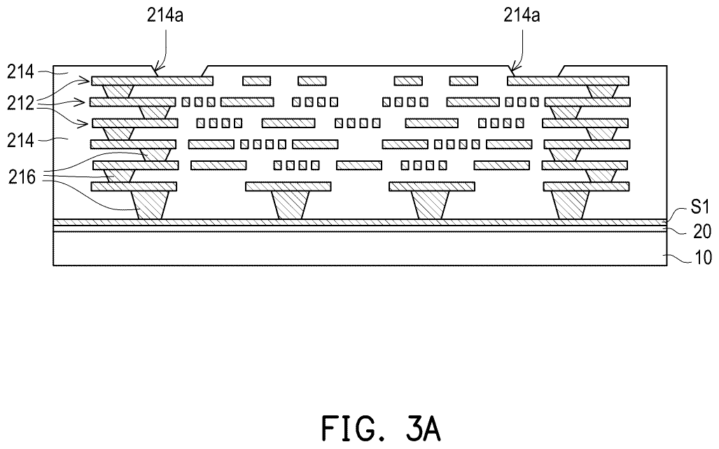

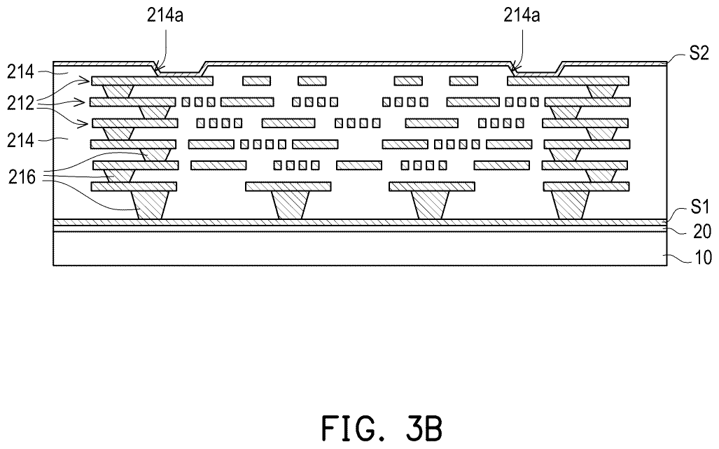

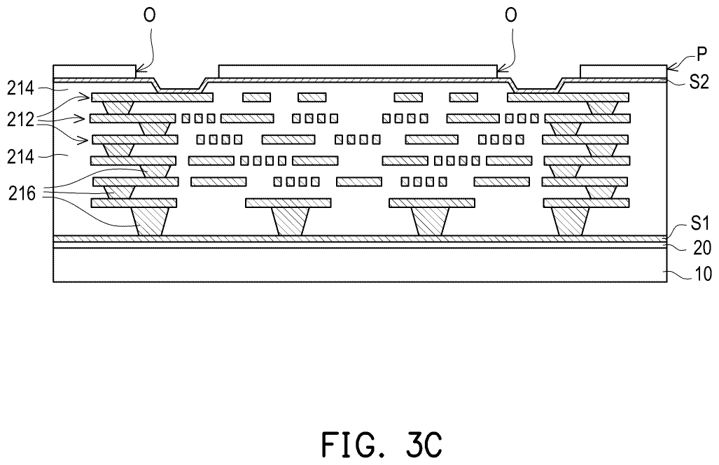

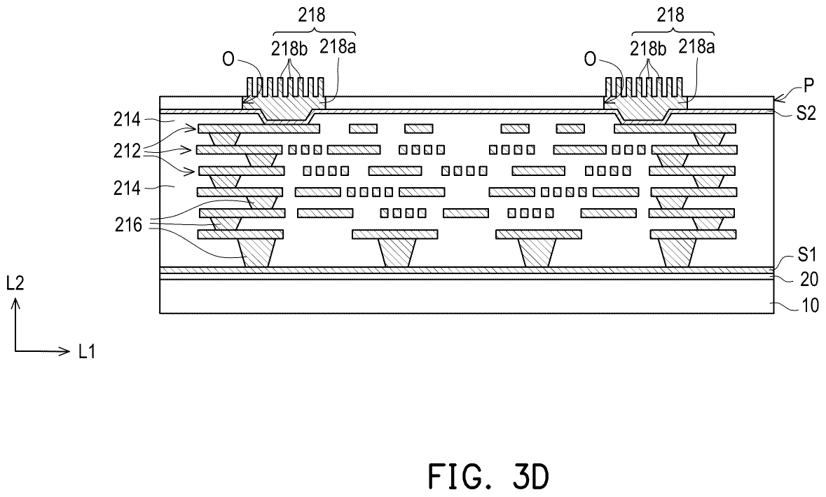

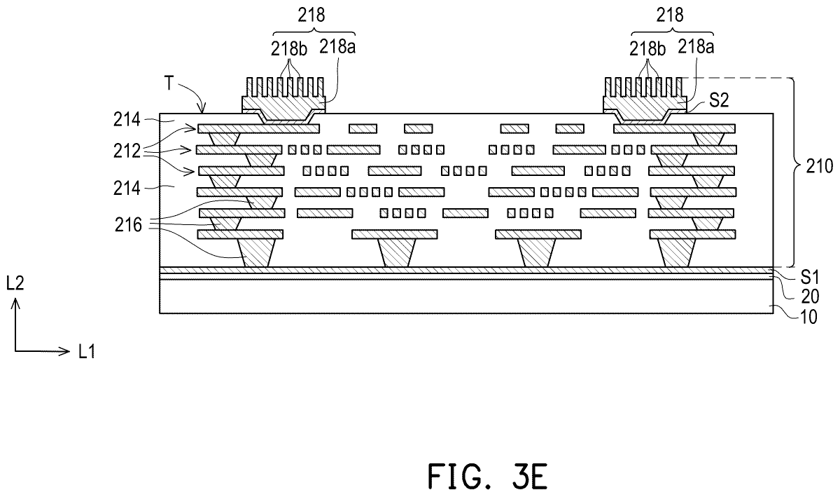

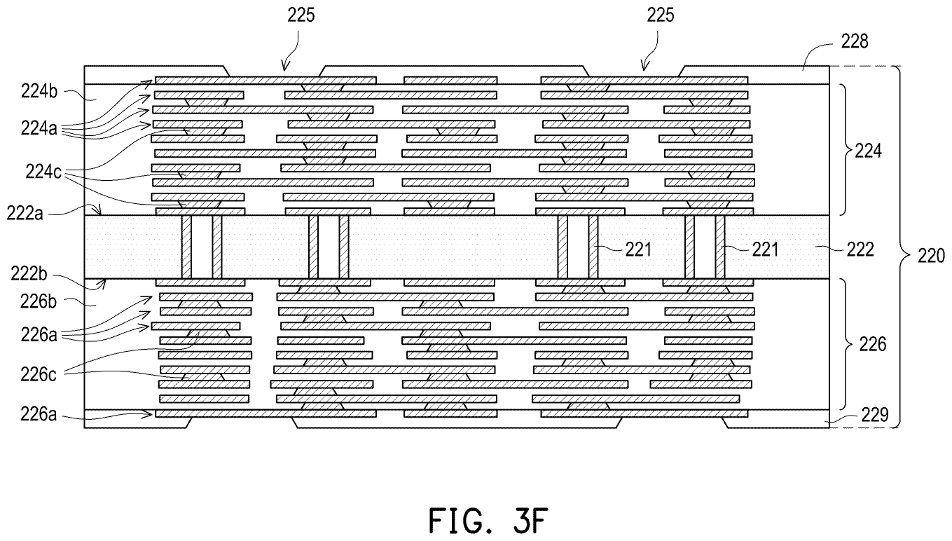

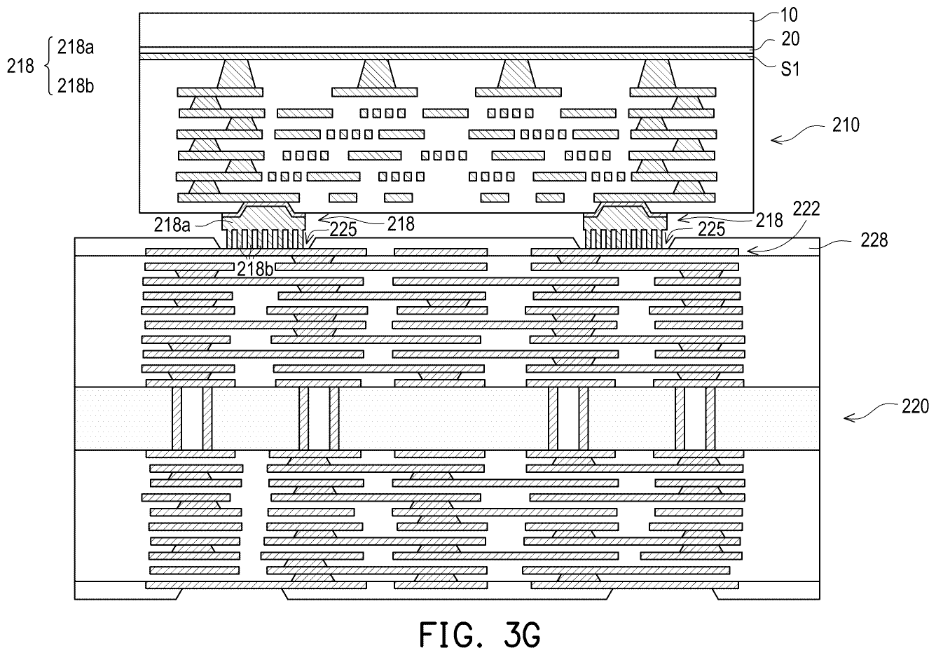

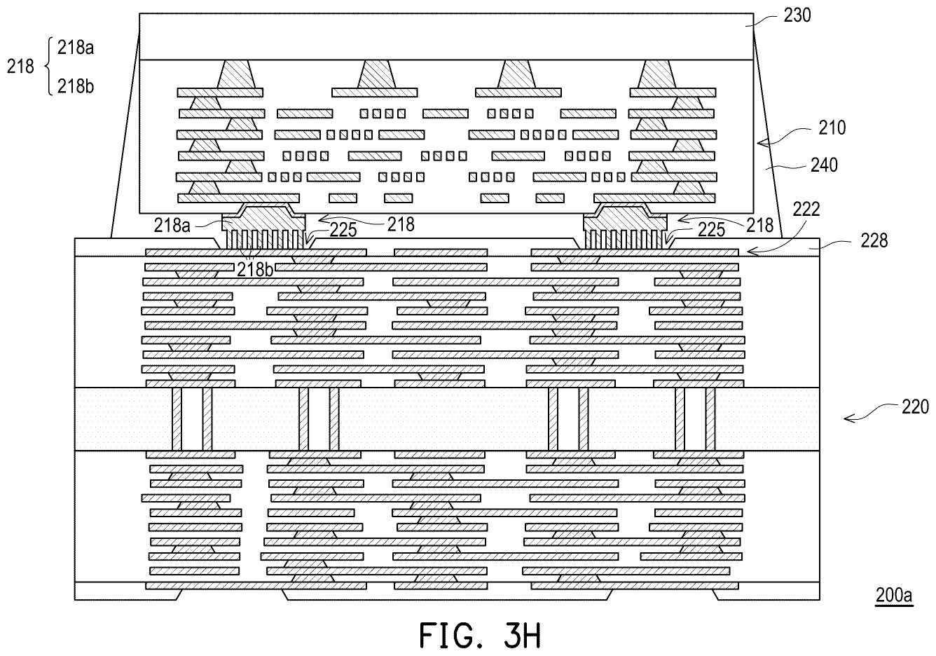

FIG. 3A to FIG. 3H are schematic cross-sectional views illustrating a manufacturing method of package structure according to an embodiment of the disclosure. According to the manufacturing method of the package structure of this embodiment, firstly, please refer to FIG. 3A. A carrier 10 is provided, and a release layer 20 is formed on the carrier 10. The carrier 10 may be a glass carrier substrate, a ceramic carrier substrate, or the like. The release layer 20 may be formed from a polymer-based material that may be removed together with the carrier 10 from the overlying structure to be formed in a subsequent step. A seed layer S1 is formed on the release layer 20. A plurality of redistribution lines 212, a plurality of dielectric layers 214 and a plurality of conductive blind holes 216 are formed on the seed layer S1. The redistribution lines 212 and the dielectric layers 214 are stacked alternately, and the redistribution lines 212 are electrically connected to each other via the conductive blind holes 216. The outermost dielectric layer 214 has a plurality of openings 214a, and the openings 214a expose a portion of the outermost conductive layer 212. In some embodiments, the material of the redistribution lines 212 is copper.

Next, referring to FIG. 3B, a seed layer S2 is formed on the outermost dielectric layer 214 and extends into the openings 214a. In some embodiments, the seed layer S2 is formed through a sputtering process, a physical vapor deposition (PVD) process, or the like. In some embodiments, the seed layer S2 is constituted by two sub-layers. In some embodiments, the material of the seed layer S2 is copper.

Next, referring to FIG. 3C, a patterned photoresist layer P is formed on the seed layer S2 by coating a wet film photoresist and by performing a photolithography on the photoresist, the patterned photoresist layer P has multiple openings O, and the openings O expose part of the seed layer S2. Meanwhile, the patterned photoresist layer P is a wet film photoresist, formed on the seed layer S2 by coating, and then lithographically etched to form the patterned photoresist layer P2.

Next, referring to FIG. 3D, the patterned photoresist layer P is used as an electroplating mask to electroplate a plurality of second pads 218 on the seed layer S2, and the second pads 218 fill the openings O and are connected to the seed layer S2. In some embodiments, the material of the second pads 218 is copper. The second pad 218 of the embodiment includes a pad portion 218a and a plurality of contact portions 218b connecting the pad portion 218a, and a first extension direction L1 of the pad portion 218a is different from a second extension direction L2 of the contact portions 218b. The contact portions 218b separately from each other are seamlessly connected to the pad portion 218a. In some embodiments, the peripheral surface of the outermost contact portions 218b is aligned with the peripheral surface of the pad portion 218a. In some embodiments, the peripheral surface of the outermost contact portions 218b is inwardly contracted to the peripheral surface of the pad portion 218a. In some embodiments, the contact portions 218b includes a plurality of nanowires, and a material of the nanowires includes copper. In some embodiments, a thickness of the nanowires is less than 3 μm, which has a lowest inductivity. In some embodiments, the first extension direction L1 is perpendicular to the second extension direction L2. In some embodiments, the structure of the second pad 218 is designed to tolerate high mechanical unevenness (e.g. >>10 μm).

Next, referring to both FIG. 3D and FIG. 3E, the patterned photoresist layer P and part of the seed layer S2 thereunder are removed to form the second pads 218 on the outermost surface T of an organic interposer 210. In some embodiments, the method of removing the patterned photoresist layer P is stripping. In some embodiments, the method of removing the seed layer S2 is etching.

Next, referring to FIG. 3F, a package substrate 220 is provided. The package substrate 220 of the embodiment includes a core layer 222, a first build-up circuit structure 224, a second build-up circuit structure 226, a solder mask layer 228 and a solder mask layer 229. The core layer 222 has a first surface 222a and a second surface 222b opposite to each other, and includes a plurality of conductive through holes 221 passing through the core layer 222. The first build-up circuit structure 224 is disposed on the first surface 222a and electrically connected to the conductive through holes 221. The first build-up circuit structure 224 includes a plurality of circuit layers 224a, a plurality of dielectric layers 224b and a plurality of conductive blind holes 224c. The circuit layers 224a and the dielectric layers 224b are stacked alternately, and the circuit layers 224a are electrically connected to each other via the conductive blind holes 224c. The solder mask layer 228 is disposed on the first build-up circuit structure 224 and exposes a portion of the outermost circuit layer 224a to define a plurality of first pads 225. In some embodiments, the material of the first pads 225 is copper. The second build-up circuit structure 226 is disposed on the second surface 222b and electrically connected to the conductive through holes 221. The second build-up circuit structure 226 includes a plurality of circuit layers 226a, a plurality of dielectric layers 226b and a plurality of conductive blind holes 226c. The circuit layers 226a and the dielectric layers 226b are stacked alternately, and the circuit layers 226a are electrically connected to each other via the conductive blind holes 226c. The solder mask layer 229 is disposed on the second build-up circuit structure 226 and exposes a portion of the outermost circuit layer 226a. In some embodiments, the package substrate 220 is ball grid array (BGA) substrate.

Next, referring to FIG. 3G, the structure illustrated in FIG. 3D is flipped upside down and is placed on the package substrate 220, and the second pads 218 are directly connected to the first pads 225, respectively, to electrically connected the organic interposer 210 to the package substrate 220. In some embodiments, a method of connecting the second pads 218 to the first pads 225 includes sintering the second pads 218 to the first pads 225 at bonding temperature of 170° C., and the bonding time is less than 10 seconds. That is to say, low temperature (170° C.) and high speed (<10 seconds) copper sintering. In some embodiments, the first pads 225 and the second pads 218 are composed of the same material, such as copper, therefore, when the second pads 218 are connected to the first pads 225, there is no contact resistance, i.e. contact 0Ω.

Next, referring to both FIG. 3G and FIG. 3H, the carrier 10, the release layer 20 and the seed layer S1 are removed, and an electronic unit 230 is provided on the organic interposer 210, wherein the electronic unit 230 is electrically connected to the package substrate 220 through the organic interposer 210. In some embodiments, the electronic unit 230 is bonded to the organic interposer 210 through flip-chip bonding. In some embodiments, the electronic unit 230 includes a system on a chip, at least one input/output circuit, an optoelectronic assembly, a combination thereof. Optionally, a underfill 240 is provided between the organic interposer 210 and the package substrate 220 to cover the second pads 218 and the first pads 225, thereby maintaining electrical performance. At the phase, the manufacturing of the package structure 200a has been completed.

In terms of the structure, referring to FIG. 3H again, the package structure 200a includes the package substrate 220, the organic interposer 210 and the electronic unit 230. The package substrate 210 includes the first pads 225. The organic interposer 210 is disposed on the package substrate 220 and includes the second pads 218. The second pads 218 are directly connected to the first pads 225 to electrically connected the organic interposer 210 to the package substrate 220. The second pad 218 includes the pad portion 218a and the contact portions 218b connecting the pad portion 218a. The first extension direction L1 of the pad portion 218a is different from the second extension direction L2 of the contact portions 218b. The electronic unit 230 is disposed on the organic interposer 210, wherein the electronic unit 230 is electrically connected to the package substrate 220 through the organic interposer 210. In some embodiments, the package structure 200a further includes the underfill 240 disposed between the organic interposer 210 and the package substrate 220 to cover the second pads 218 and the first pads 225.

In the design of the package structure 200a of the embodiment, the second pads 218 are directly connected to the first pads 225 to electrically connected the organic interposer 210 to the package substrate 220, wherein the second pad 218 includes the pad portion 218a and the contact portions 218b connecting the pad portion 218a. That is, instead of using the solder ball, the present embodiment directly connects the second pads 218 to the first pads 225 to achieve a stress-free bonding and the pitch between the pads can be effectively reduced (i.e. to less than 100 μm, preferably less than 40 μm), and thus the package structure 200a of the embodiment may have low cost and high structural reliability. In summary, the present embodiment employs a single metal (i.e. copper) for the bonding process, thereby achieving the advantages of stress-free connection and low-temperature interconnection.

It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

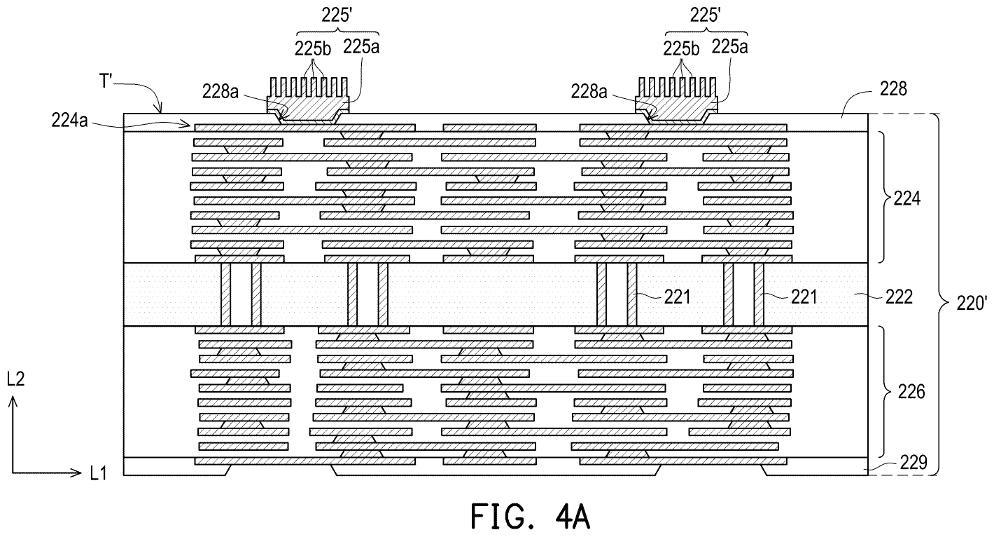

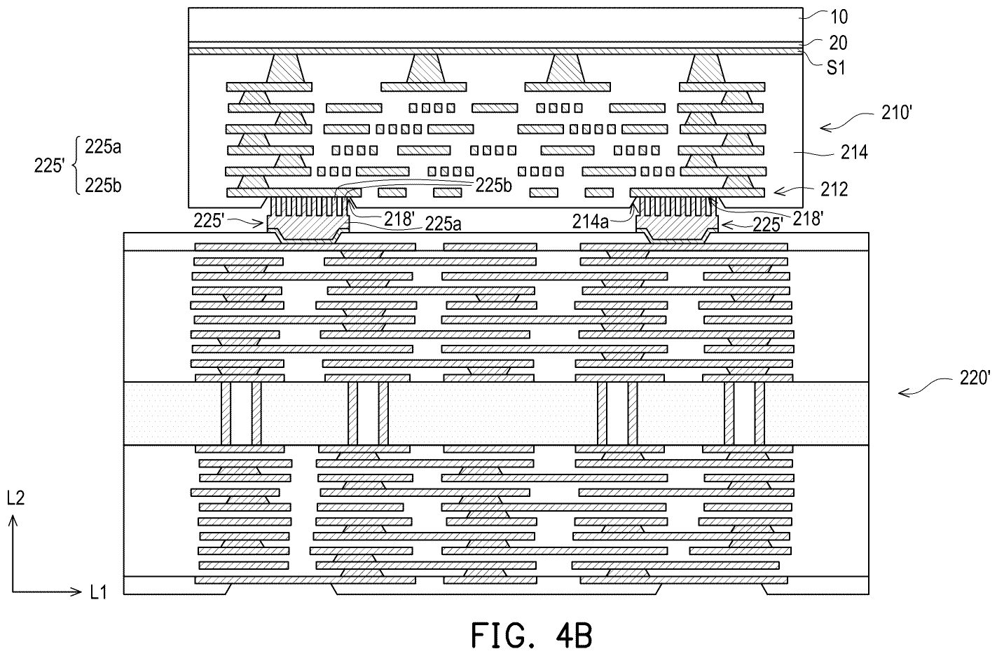

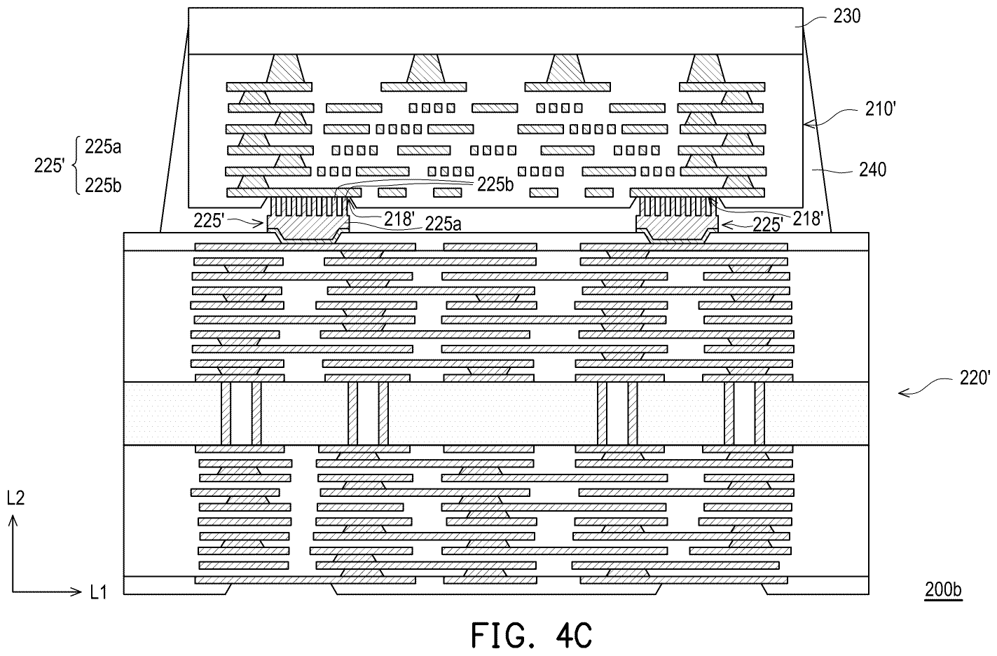

FIG. 4A to FIG. 4C are schematic cross-sectional views illustrating partial steps of a manufacturing method of package structure according to another embodiment of the disclosure. Referring to FIG. 3F and FIG. 4A at the same time, the manufacturing method of the package structure of this embodiment is similar to the manufacturing method of the above-mentioned package structure. The main difference between the two is that the first pad 225′ of the package substrate 220′ includes a pad portion 225a and a plurality of contact portions 225b connecting the pad portion 225a, and the first extension direction L1 of the pad portion 225a is different from the second extension direction L2 of the contact portions 225b. The first pads 225′ are respectively disposed on the openings 228a of the solder mask layer 228 and extends to the outermost surface T′ of the package substrate 220′. The first pads 225′ are electrically connected to the circuit layers 224a. In some embodiments, the contact portions 225′ includes plurality of nanowires, and a material of the nanowires includes copper. In some embodiments, a thickness of the nanowires is less than 3 μm. In some embodiments, the first extension direction L1 is perpendicular to the second extension direction L2.

Next, referring to FIG. 3G and FIG. 4B at the same time. The main difference between the two is that the outermost dielectric layer 214 has a plurality of opening 214a, and the opening 214a exposes a portion of the outermost redistribution line 212 to define the second pads 218′. And, then, referring to FIG. 4B, the second pads 218′ are directly connected to the first pads 225′, respectively, to electrically connected the organic interposer 210′ to the package substrate 220′. In some embodiments, a method of connecting the second pads 218′ to the first pads 225′ includes welding or sintering the second pads 218′ to the first pads 225′ at bonding temperature of 170° C., and the bonding time is less than 10 seconds. That is to say, low temperature (170° C.) and high speed (<10 seconds) copper sintering. In some embodiments, the first pads 225′ and the second pads 218′ are composed of the same material, such as copper, therefore, when the second pads 218′ are connected to the first pads 225′, there is no contact resistance, i.e. contact 0Ω.

Next, referring to both FIG. 4B and FIG. 4C, the carrier 10, the release layer 20 and the seed layer S1 are removed, and an electronic unit 230 is provided on the organic interposer 210′, wherein the electronic unit 230 is electrically connected to the package substrate 220′ through the organic interposer 210′. In some embodiments, the electronic unit 230 includes a system on a chip, at least one input/output circuit, an optoelectronic assembly, a combination thereof. And then, a underfill 240 is provided between the organic interposer 210′ and the package substrate 220′ to cover the second pads 218′ and the first pads 225′. At the phase, the manufacturing of the package structure 200b has been completed.

In the design of the package structure 200b of the embodiment, the second pads 218′ are directly connected to the first pads 225′ to electrically connected the organic interposer 210′ to the package substrate 220′, wherein the first pad 225′ includes the pad portion 225a and the contact portions 225b connecting the pad portion 225a. That is, instead of using the solder ball, the present embodiment directly connects the second pads 218′ to the first pads 225′ to achieve a stress-free bonding and the pitch between the pads can be effectively reduced (i.e. to less than 100 μm, preferably less than 40 μm), and thus the package structure 200b of the embodiment may have low cost and high structural reliability. In summary, the present embodiment employs a single metal (i.e. copper) for the bonding process, thereby achieving the advantages of stress-free connection and low-temperature interconnection.

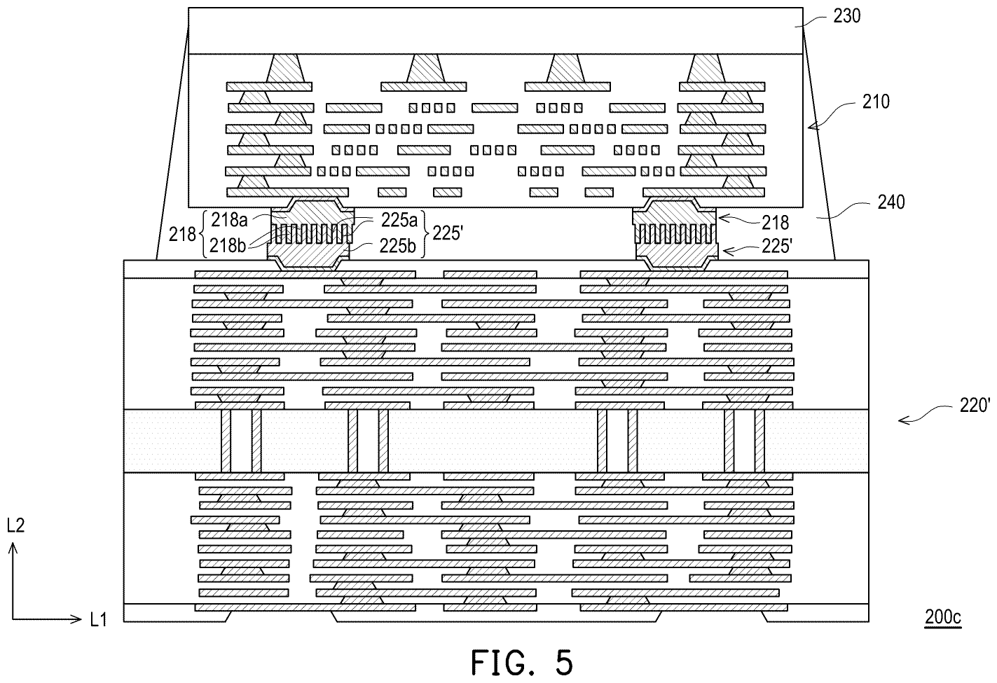

FIG. 5 is a schematic cross-sectional view of a package structure according to an embodiment of the disclosure. Referring to FIG. 4C and FIG. 5 at the same time, the package structure 200c of this embodiment is similar to the above-mentioned package structure 200b. The main difference between the two is that the second pad 218 of the embodiment also includes a pad portion 218a and a plurality of contact portions 218b connecting the pad portion 218a, and a first extension direction L1 of the pad portion 218a is different from a second extension direction L2 of the contact portions 218b. The contact portions 218b of the second pad 218 is staggered with the contact portion 225b of the first pad 225′. In some embodiments, the second pad 218 is connected in correspondence with the first pad 225′. In some embodiments, the second pad 218 and the first pad 225′ are misaligned in their connection. In some embodiments, a method of connecting the second pads 218 to the first pads 225′ includes welding the second pads 218 to the first pads 225′ at room temperature, and the bonding time is 100 milliseconds.

In summary, the effect of a stress-free bonding and reducing the pitch between the pads can be achieved as long as at least one of each of the first pads 218 and each of the second pads 225′ includes the pad portion 218a, 225a and the contact portions 218b, 225b connecting the pad portion 218a, 225a. In some embodiments, the aforementioned bonding method between the second pads 218, 218′ and the first pads 225, 225′ can be applied to the joining of hybrid system, such as μLED/Amplifier, Diode/Amplifier, μC/D-Ram.

Based on the above, in the design of the package structure of the disclosure, the second pads are directly connected to the first pads to electrically connected the organic interposer to the package substrate, wherein at least one of each of the first pads and each of the second pads includes a pad portion and a plurality of contact portions connecting the pad portion. That is, instead of using the solder ball, the present disclosure directly connects the second pads to the first pads to achieve a stress-free bonding and the pitch between the pads can be effectively reduced (i.e. to less than 100 μm, preferably less than 40 μm), and thus the package structure of the disclosure may have low cost and high structural reliability.

Although the disclosure has been described with reference to the above embodiments, the described embodiments are not intended to limit the disclosure. People of ordinary skill in the art may make some changes and modifications without departing from the spirit and the scope of the disclosure. Thus, the scope of the disclosure shall be subject to those defined by the attached claims.

What is claimed is:

1. A package structure, comprising:
a package substrate, comprising a plurality of first pads;
an organic interposer, disposed on the package substrate and comprising a plurality of second pads, the plurality of the second pads directly connected to the plurality of the first pads to electrically connected the organic interposer to the package substrate, wherein at least one of each of the plurality of first pads and each of the plurality of second pads comprises a pad portion and a plurality of contact portions connecting the pad portion, a first extension direction of the pad portion is different from a second extension direction of the plurality of contact portions; and
an electronic unit, disposed on the organic interposer, wherein the electronic unit is electrically connected to the package substrate through the organic interposer.

2. The package structure according to claim 1, wherein the first extension direction is perpendicular to the second extension direction.

3. The package structure according to claim 1, wherein the plurality of contact portions comprises a plurality of nanowires.

4. The package structure according to claim 3, wherein a material of the plurality of nanowires comprises copper.

5. The package structure according to claim 3, wherein a thickness of the plurality of nanowires is less than 3 μm.

6. The package structure according to claim 1, wherein the electronic unit comprises a system on a chip, at least one input/output circuit, an optoelectronic assembly, a combination thereof.

7. A manufacturing method of a package structure, comprising:
providing a package substrate and an organic interposer, the package substrate comprising a plurality of first pads, the organic interposer comprising a plurality of second pads, wherein at least one of each of the plurality of first pads and each of the plurality of second pads comprises a pad portion and a plurality of contact portions connecting the pad portion, a first extension direction of the pad portion is different from a second extension direction of the plurality of contact portions;
connecting the plurality of the second pads to the plurality of the first pads to electrically connected the organic interposer to the package substrate; and
providing an electronic unit on the organic interposer, wherein the electronic unit is electrically connected to the package substrate through the organic interposer.

8. The manufacturing method of the package structure according to claim 7, further comprising:
providing a underfill between the electronic unit and the organic interposer.

9. The manufacturing method of the package structure according to claim 7, wherein a method of connecting the plurality of the second pads to the plurality of the first pads comprises sintering the plurality of the second pads to the plurality of the first pads at bonding temperature of 170° C. or welding the plurality of the second pads to the plurality of the first pads at room temperature.

10. The manufacturing method of the package structure according to claim 7, wherein the plurality of contact portions comprises a plurality of nanowires.
